(19) United States
(12) Patent Application Publication
(10) Pub. No.: US 2025/0386653 A1
(43) Pub. Date: Dec. 18, 2025

(54) DISPLAY DEVICE INCLUDING DISPLAY MODULE

(71) Applicant: SAMSUNG ELECTRONICS CO., LTD., Suwon-si (KR)

(72) Inventors: NARAE SHIN, Suwon-si (KR); SOYOUNG LIM, Suwon-si (KR)

(21) Appl. No.: 19/058,903

(22) Filed: Feb. 20, 2025

(30) Foreign Application Priority Data
Jun. 14, 2024 (KR) 10-2024-0077628

(51) Int. Cl. H10H 29/85; H01L 25/075

(52) U.S. Cl. CPC H10H 29/857; H01L 25/0753

(57) ABSTRACT

A display module includes a display substrate including a front surface and a rear surface opposite to the front surface, an array of pixels on the front surface, wherein a plurality of micro light emitting diodes (LEDs) are in each pixel, a plurality of through vias in the display substrate and that extend from the front surface to the rear surface, a printed circuit board (PCB) on the rear surface of the display substrate, and a film substrate on the rear surface of the display substrate and including a first coupling portion coupled to at least one of the through vias, a second coupling portion coupled to the PCB, and a connection portion that connects the first coupling portion and the second coupling portion. Each of the through vias is electrically connected to at least one pixel in the array of pixels.

### CROSS-REFERENCE TO RELATED APPLICATION

This application claims the benefit of Korean Patent Application No. 10-2024-0077628 filed on Jun. 14, 2024, in the Korean Intellectual Property Office, the entire disclosure of which is incorporated herein by reference in its entirety.

### BACKGROUND

### 1. Field of the Invention

One or more embodiments relate to a display module including a micro light emitting diode (LED), and a display device including the display module.

### 2. Description of the Related Art

Display devices may be divided into self-light emitting displays, in which each pixel emits light on their own, and light emitting and receiving displays, which require a separate light source. In the case of a self-light emitting display, a light emitting element is disposed in each pixel, and components such as a separate light source and a backline unit are omitted, thereby realizing a thin thickness and a high degree of design freedom.

Among self-light emitting displays, a micro light emitting diode (LED) display includes a plurality of LEDs with a size of about 100 micrometers. A micro LED is an inorganic light emitting element, and has more excellent light emitting efficiency and service life than organic light emitting elements, because a separate encapsulation layer to protect organic substances may be omitted. The above description is information the inventor(s) acquired during the course of conceiving the present disclosure, or already possessed at the time, and is not necessarily art publicly known before the present application was filed.

### SUMMARY OF THE INVENTION

A goal achieved by the present disclosure is to realize a bezel-less display area by connecting a micro light emitting diode (LED) to an external circuit through a through glass via (TGV) formed on a glass panel instead of a separate side wire.

Another goal achieved by the present disclosure is to secure a degree of freedom in a position of a display driver IC (DDI) on a display module so that a further improved heat dissipation design of the display module may be implemented.

However, goals achieved are not limited to those described above, and other goals not mentioned above are clearly understood by one of ordinary skill in the art from the following description.

According to an aspect, there is provided a display module including a display substrate having a front surface and a rear surface opposite to the front surface, an array of pixels on the front surface of the display substrate, wherein a plurality of micro light emitting diodes (LEDs) are in each pixel in the array of pixels, a plurality of through vias in the display substrate that extend from the front surface of the display substrate to the rear surface of the display substrate, a printed circuit board (PCB) on the rear surface of the display substrate, and a film substrate on the rear surface of the display substrate and including a first coupling portion coupled to at least one of the plurality of through vias, a second coupling portion coupled to the PCB, and a connection portion that connects the first coupling portion and the second coupling portion. Each of the plurality of through vias may be electrically connected to at least one pixel in the array of pixels. The film substrate may include an insulating film, a wiring layer on at least a portion of a surface of the insulating film, wherein the wiring layer includes at least one wire extending from the first coupling portion and the second coupling portion, and a display driver IC (DDI) on a surface of the film substrate and electrically connected to the at least one wire.

The film substrate may include a first surface facing the rear surface of the display substrate and a second surface opposite to the first surface. At least one first coupling pad connected to the at least one wire may be formed on the first surface of the film substrate at the first coupling portion, and at least one second coupling pad connected to the at least one wire may be formed on the second surface of the film substrate at the second coupling portion.

At least one coupling area is on the rear surface of the display substrate, wherein the at least one coupling area includes at least one first connection pad, and wherein the at least one first connection pad may be electrically connected to a respective one of the plurality of through vias. The first coupling portion of the film substrate may be bonded to the at least one coupling area so that the at least one first coupling pad is coupled to the at least one first connection pad.

The at least one coupling area is spaced apart from an outer perimeter of the PCB.

The display module may further include a lower redistribution layer on the rear surface of the display substrate, wherein the lower distribution layer includes a redistribution line that connects the respective one of the plurality of through vias and the at least one first connection pad.

The display module may further include a first conductive bonding film between the at least one first connection pad and the at least one first coupling pad.

At least one second connection pad electrically connected to a circuit line of the PCB may be on a surface of the PCB. The second coupling portion of the film substrate may be bonded to a surface of the PCB so that the at least one second coupling pad is coupled to the at least one second connection pad.

The display module may further include a second conductive bonding film between the at least one second connection pad and the at least one second coupling pad.

The PCB may include at least one connector electrically connected to a circuit line of the PCB. The second coupling portion of the film substrate may be detachably fastened to the at least one connector.

The film substrate may further include a reinforcing member on the second surface of the film substrate at the second coupling portion, wherein the reinforcing member is configured to provide rigidity to the second coupling portion.

The film substrate may include a first wiring layer having at least one first wire on the first surface of the film substrate. The DDI may be on the first surface of the film substrate, and may be electrically connected to the at least one first wire.

The film substrate may include a first wiring layer having at least one first wire on the first surface of the film substrate, a second wiring layer having at least one second wire on the second surface of the film substrate, and at least one connection via that penetrates the first surface and the second surface of the film substrate and electrically connects the first wiring layer and the second wiring layer. The DDI may be on the second surface of the film substrate and electrically connected to the at least one second wire in the connection portion.

The first wiring layer may include at least one (1-1)-th wire extending from the first coupling portion to the connection portion, and at least one (1-2)-th wire extending from the second coupling portion to the connection portion. The film substrate includes at least one connection via and the at least one connection via may include at least one first connection via in the connection portion and electrically connecting the (1-1)-th wire and the second wire, and at least one second connection via in the connection portion and electrically connecting the (1-2)-th wire and the second wire.

The second coupling portion of the film substrate may have a thickness greater than a thickness of the connection portion.

The film substrate may further include a protective layer that covers the at least one first wire. The at least one first wire is exposed on at least a portion of a mounting area for a semiconductor chip.

According to another aspect, a display device may include a plurality of display modules arranged in an array. Each of the display modules may include an array of pixels on a front surface of a display substrate, wherein a plurality of micro LEDs are in each pixel, a plurality of through vias penetrate the display substrate and extend from the front surface of the display substrate to a rear surface of the display substrate, a PCB on the rear surface of the display substrate, and a film substrate on the rear surface of the display substrate and including a first coupling portion coupled to at least one of the plurality of through vias, a second coupling portion coupled to the PCB, and a connection portion that connects the first coupling portion and the second coupling portion. Each of the plurality of through vias may be electrically connected to at least one pixel in the array of pixels. The film substrate may include an insulating film, a wiring layer on at least a portion of a surface of the insulating film, wherein the wiring layer includes at least one wire extending from the first coupling portion and the second coupling portion, and a DDI on the surface and electrically connected to the at least one wire.

The film substrate may include a first surface facing the rear surface of the display substrate and a second surface opposite to the first surface. At least one first coupling pad is connected to each at least one wire on the first surface of the first coupling portion, and at least one second coupling pad is connected to each at least one wire on the second surface of the second coupling portion.

Each of the display modules may further include a plurality of first connection pads on the rear surface of the display substrate, and a lower redistribution layer on the rear surface of the display substrate, and that includes a redistribution line for connecting the plurality of through vias and the plurality of first connection pads. Each of the display modules includes at least one coupling area, where at least one of the plurality of first connection pads is on the rear surface of the display substrate and the first coupling portion of the film substrate may be bonded to the coupling area so that the at least one first coupling pad is coupled to a respective one of the plurality of first connection pads.

Each of the display modules includes at least one second connection pad on a surface of the PCB that is electrically connected to a circuit line of the PCB, and the film substrate is connected to the PCB so that the at least one second coupling pad is coupled to the at least one second connection pad. The first coupling portion may be bonded to the PCB or detachably fastened to a connector on the PCB.

According to still another aspect, there is provided a display module including a display substrate including a front surface and a rear surface opposite to the front surface, an array of pixels on the front surface of the display substrate, wherein a plurality of micro LEDs are in each pixel, a plurality of through vias in the display substrate that extend from the front surface of the display substrate to the rear surface of the display substrate, a PCB on the rear surface of the display substrate, and a film substrate on the rear surface of the display substrate and including a first coupling portion coupled to at least one of the plurality of through vias, a second coupling portion coupled to the PCB, and a connection portion that connects the first coupling portion and the second coupling portion. Each of the plurality of through vias may be electrically connected to at least one pixel in the array of pixels. The film substrate may include an insulating film, a wiring layer on at least a portion of a surface of the insulating film, wherein the wiring layer includes at least one wire extending from the first coupling portion and the second coupling portion, and a DDI on a surface of the film substrate and electrically connected to the at least one wire. The film substrate may include a first surface facing the display substrate and a second surface opposite to the first surface, and wherein the at least one wire is exposed through the film substrate first surface at the first coupling portion and at the second coupling portion. The first coupling portion may be bonded onto the rear surface of the display substrate so that the exposed at least one wire is electrically connected to the at least one of the plurality of through vias. The second coupling portion may be connected to the PCB so that the exposed at least one wire is electrically connected to a circuit line of the PCB. Additional aspects of embodiments will be set forth in part in the description which follows and, in part, will be apparent from the description, or may be learned by practice of the disclosure.

A display module according to the present disclosure may secure an active area of a bezel-less display module by connecting a pixel area formed on a front surface of a display substrate and a PCB disposed on a rear surface through a through via formed on the display substrate and a film substrate disposed on the rear surface of the display substrate. In addition, since the film substrate is directly coupled to the PCB on the rear surface of the display substrate, a degree of freedom of a DDI in the display module may be improved.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a perspective view of a display device according to an embodiment;

FIG. 2 is a front view of a display module according to an embodiment;

FIG. 3 is a rear view of a display module according to an embodiment;

FIG. 4A is an exemplary cross-sectional view of a display module taken along line A-A′ of FIG. 3;

FIG. 4B is an enlarged cross-sectional view of a film substrate shown in FIG. 4A;

FIG. 4C is an enlarged cross-sectional view of an exemplary film substrate;

FIG. 5 is an exemplary cross-sectional view of a display module taken along line A-A′ of FIG. 3;

FIG. 6A is an exemplary cross-sectional view of a display module taken along line A-A′ of FIG. 3; and

FIG. 6B is an enlarged cross-sectional view of a film substrate shown in FIG. 6A.

### DETAILED DESCRIPTION

Hereinafter, embodiments will be described in detail with reference to the accompanying drawings. However, various alterations and modifications may be made to the embodiments and thus, the scope of the disclosure is not limited or restricted to the embodiments. The equivalents should be understood to include all changes, equivalents, and replacements within the idea and the technical scope of the disclosure.

The terminology used herein is for the purpose of describing particular embodiments only and is not to be limiting of the embodiments. The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, the terms first, second, A, B, (a), and (b) may be used to describe constituent elements of the embodiments. These terms are used only for the purpose of discriminating one component from another component, and the nature, the sequences, or the orders of the components are not limited by the terms. It should be noted that if it is described that one component is “connected”, “coupled”, or “joined” to another component, a third component may be “connected”, “coupled”, and “joined” between the first and second components, although the first component may be directly connected, coupled, or joined to the second component.

A component, which has the same common function as a component included in any one embodiment, will be described by using the same name in other embodiments. Unless disclosed to the contrary, the description of any one embodiment may be applied to other embodiments, and the specific description of the repeated configuration will be omitted.

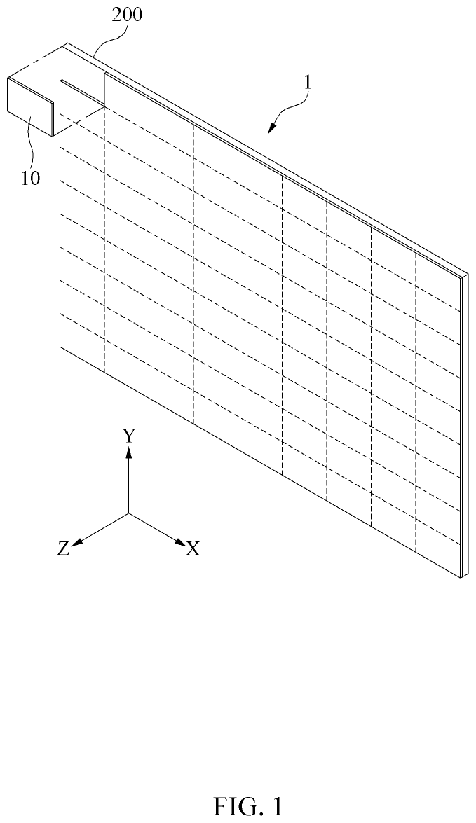

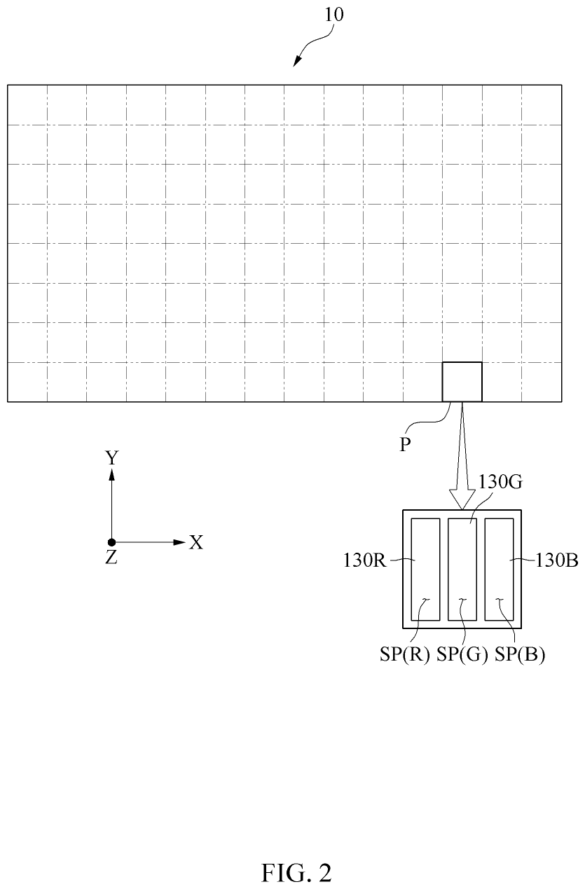

FIG. 1 is a perspective view of a display device according to an embodiment. FIG. 2 is a front view of a display module according to an embodiment.

Referring to FIG. 1, a display device 1 according to an embodiment may include a plurality of display modules 10 each including a screen displaying an image. Each display module 10 may form a screen through an array of pixels arranged in a matrix form, and a plurality of inorganic light emitting elements, for example, three inorganic light emitting elements showing different colors, may be disposed in each unit pixel. The inorganic light emitting element may be a micro light emitting diode (LED) with a length of a short side of about 100 micrometers.

The plurality of display modules 10 may be arranged on a support 200 so that each screen is oriented in the same direction (e.g., a +Z direction) to implement a large screen. FIG. 1 shows an example in which the display device 1 implements a large screen by using the plurality of display modules 10, however, the display device 1 may include only a single display module 10 to form screens of a television (TV), a wearable device, a portable device, etc.

Referring to FIG. 2, the display module 10 may include an array of a plurality of pixels arranged in a matrix form, for example, two-dimensionally. At least three subpixels that output light of different colors may be formed in each pixel P. For example, in each pixel P, a red subpixel SP(R) that outputs red light, a green subpixel SP(G) that outputs green light, and a blue subpixel SP(B) that outputs blue light may be formed. The arrangement of the subpixels within the pixel P shown in FIG. 2 is merely an example, and it should be noted that the arrangement of each subpixel SP and the relative size of each subpixel SP may be implemented differently from those shown in the drawing. In addition, the red subpixel SP(R), the green subpixel SP(G), and the blue subpixel SP(B) do not necessarily have to be disposed in one pixel P, and a subpixel that outputs yellow or white light may also be disposed. Hereinafter, for convenience of description, an embodiment in which red subpixel SP(R), the green subpixel SP(G), and the blue subpixel SP(B) are disposed in one pixel will be described as an example.

A micro LED that outputs light of different colors may be disposed in each subpixel SR. For example, a first micro LED 130R that outputs red light may be disposed in the red subpixel SP(R), a second micro LED 130G that outputs green light may be disposed in the green subpixel SP(G), and a third micro LED 130B that outputs blue light may be disposed in the blue subpixel SP(B). Although not shown in the drawing, a driving circuit may be formed in each subpixel SR to drive the micro LED disposed in the corresponding subpixel. Since each driving circuit is formed in sub-pixel units, it may also be referred to as a sub-pixel circuit. The driving circuit may receive a gate signal and a data signal, and output a driving current to drive the corresponding micro LED. In this case, each micro LED may emit light by the input driving current. Each micro LED may be driven by an active matrix (AM) method or a passive matrix (PM) method, but for convenience of description, a case where the micro LED is driven by the AM method will be described below as an example.

As will be described below, the display module 10 does not include an inactive area for side wiring other than an active area where the array of pixels P is arranged to display a screen. Therefore, it is possible to implement a bezel-less display, i.e., a display without a bezel. In this case, when the plurality of display modules 10 are arranged side by side as shown in FIG. 1, the visibility of a boundary between adjacent display modules 10 may be greatly reduced.

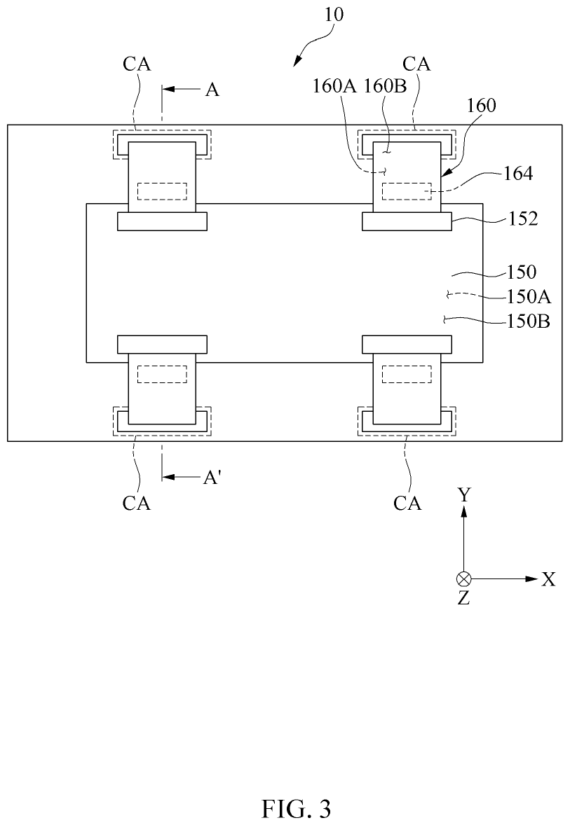

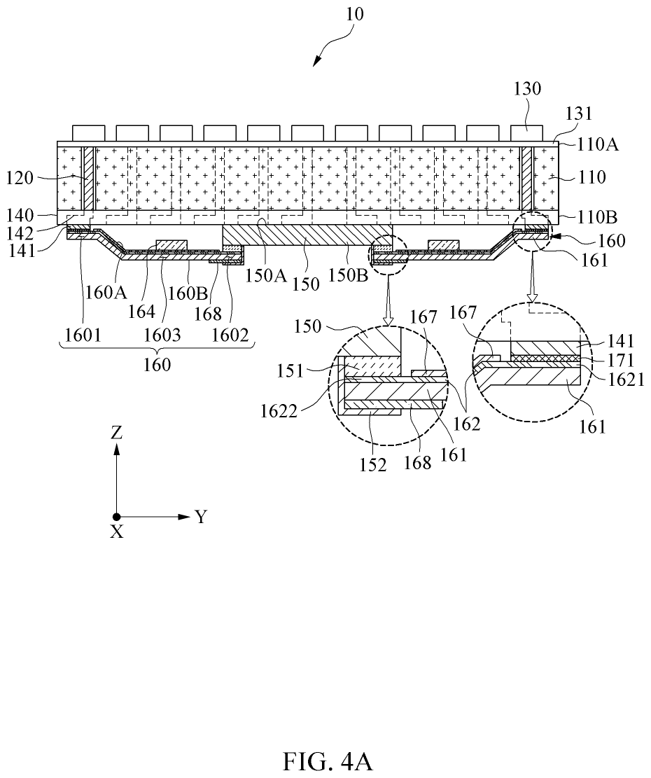

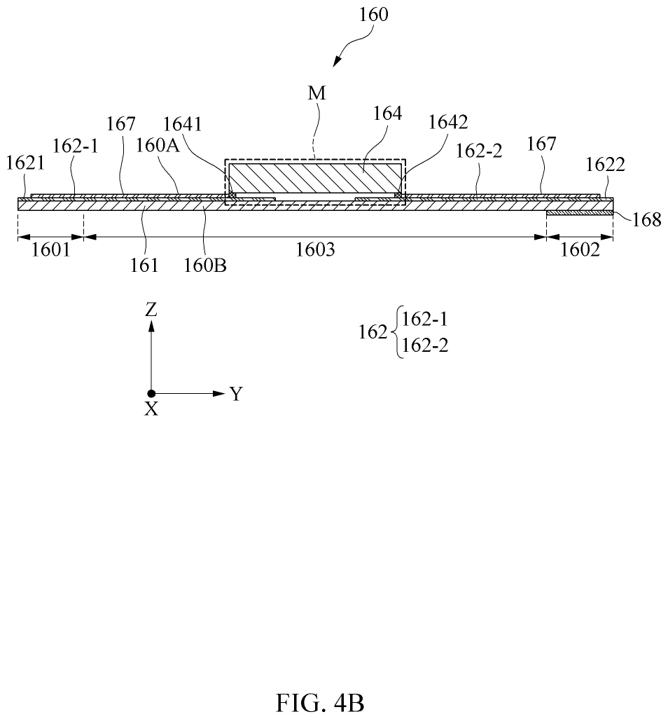

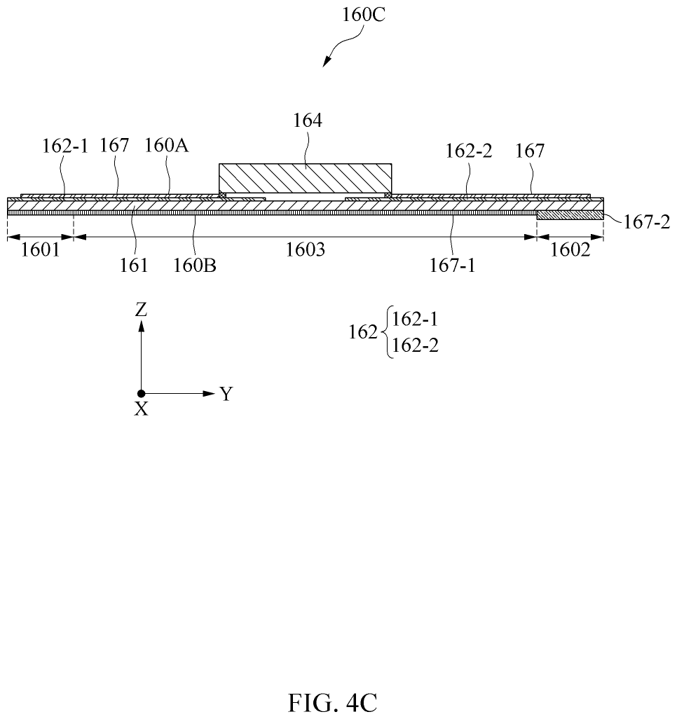

FIG. 3 is a rear view of a display module according to an embodiment. FIG. 4A is an exemplary cross-sectional view of a display module taken along line A-A′ of FIG. 3. FIG. 4B is an enlarged cross-sectional view of a film substrate shown in FIG. 4A.

Referring to FIGS. 3, 4A, and 4B, the display module 10 according to an embodiment may include a display substrate 110, a plurality of micro LEDs 130, a plurality of through vias 120 formed on the display substrate 110, a printed circuit board (PCB) 150 disposed on a rear surface of the display substrate 110, and a film substrate 160 electrically coupled to each of the through via 120 and the PCB 150 at the rear surface of the display substrate 110.

The display substrate 110 may include a front surface (a surface facing the +Z direction) and a rear surface (a surface facing a −Z direction) opposite to the front surface. A display area, where a screen is output through an array of pixels, may be formed on the front surface of the display substrate 110. A driving circuit layer 131 may be formed on the front surface of the display substrate 110, and the plurality of micro LEDs 130 may be arranged in an array on the driving circuit layer 131. The plurality of micro LEDs 130 may form a pixel array. The plurality of micro LEDs 130, for example, three micro LEDs 130 emitting light of different colors, may be disposed in each pixel.

The display substrate 110 may include at least one material of glass, amorphous silicon, polysilicon, single crystal silicon, metal foil, metal foil wrapped with a dielectric material, or a polymer material, for example, polyimide (PI), polymethyl methacrylate (PMMA), polyethylene terephthalate (PET), polyethylene naphthalate (PEN), polycarbonate (PC), polyethersulfone (PES), aromatic fluorine-containing polyarylate (PAR), and polycyclic olefin (PCO). For example, the display substrate may be a glass substrate.

The driving circuit layer 131 may include various circuits for driving the micro LEDs 130. For example, the driving circuit layer 131 may transmit a driving current with controlled magnitude and driving time to each micro LED 130 based on a data voltage, a driving voltage, and various control signals applied from the outside. For example, the driving circuit may drive the micro LED 130 using pulse amplitude modulation (PAM) and/or pulse width modulation (PWM) to control the brightness of the light emitted by the micro LED 130. The driving circuit may include a PAM circuit for providing a driving current with a magnitude corresponding to a PAM data voltage to the micro LED 130, and/or a PWM circuit for providing a driving current provided from the PAM circuit to an inorganic light emitting element for a time corresponding to the PWM data voltage.

The driving circuit layer 131 may be implemented as a thin film transistor (TFT) on the front surface of the display substrate 110. A driving circuit for driving each micro LED 130 may be formed in the driving circuit layer 131 to correspond to each micro LED 130. The micro LED 130 may be disposed on the driving circuit layer 131 to be electrically connected to the driving circuit of the corresponding driving circuit layer 131. For example, the micro LED 130 may be disposed on the driving circuit layer 131 such that an anode electrode and a cathode electrode are connected to the corresponding driving circuit. According to an embodiment, the driving circuit formed on the driving circuit layer 131 may function as a common electrode of the plurality of micro LEDs 130.

The plurality of through vias 120 formed to penetrate the display substrate 110 may be formed in the display substrate 110 to extend from the front surface to the rear surface thereof. Each of the through vias 120 may be formed using a variety of techniques such as chemical etching or laser drilling, however embodiments are not limited thereto. Each of the through vias 120 shown in the drawing may be a single through via 120 formed through the display substrate 110. However, this is merely for convenience of description, and it should be noted that each of the through vias 120 may be replaced by a series of wires and vias passing through a plurality of layers of the display substrate 110. When the display substrate 110 is formed of a glass material, each of the through vias 120 may be formed through a through-glass via (TGV) process. Each of the through vias 120 may be formed through a via hole penetrating the display substrate 110. A conductive metal material, for example, copper, may be plated on an inner surface of the via hole, and a conductive or insulating filler material may be disposed therein.

Each of the through vias 120 may be connected to the driving circuit layer 131 on the front surface of the display substrate 110 to be connected to at least one pixel among the plurality of pixels. For example, when a plurality of driving circuits corresponding to the plurality of pixels is formed in the driving circuit layer 131, each of the through vias 120 may be electrically connected to one pixel. In contrast, when the driving circuit formed in the driving circuit layer 131 is connected to the plurality of pixels, each of the through vias 120 may be electrically connected to the plurality of pixels.

A lower redistribution layer 140 may be stacked on the rear surface of the display substrate 110. The lower redistribution layer 140 may be formed of a single layer or a plurality of layers. A plurality of redistribution lines 142 electrically connected to plurality of the through vias 120 extending to the rear surface of the display substrate 110 may be formed in the lower redistribution layer 140. Each redistribution line 142 formed in the lower redistribution layer 140 may extend from each corresponding through via 120 to one coupling area CA among a plurality of coupling area CA formed on the rear surface of the display substrate 110.

A plurality of first connection pads 141 electrically connected to the redistribution lines 142 extending to the coupling area CA and exposed to the outside of the lower redistribution layer 140 may be formed on the rear surface of the display substrate 110. Each of the first connection pads 141 may be electrically connected to each one of the plurality of through vias 120 through the lower redistribution layer 140. In the drawing, for convenience of description, it is shown that one redistribution line 142 is connected to the first connection pads 141 positioned at both ends (e.g., both ends in an X-axis direction of FIG. 4A) of the display module 10, however, this is for convenience of description, and it should be noted that the redistribution lines 142 formed in the lower redistribution layer 140 may be formed in the lower redistribution layer 140 to connect one first connection pad 141 of the plurality of first connection pads 141 positioned in the coupling area CA to the corresponding through via 120. In addition, it should be noted that a formation position of the first connection pad 141 corresponding to each through via 120 may be a position of one coupling area of the plurality of coupling areas CA according to the design of the display module 10.

As shown in FIG. 3, the PCB 150 may be disposed on the rear surface of the display substrate 110. The PCB 150 may include a first circuit board surface 150A facing the display substrate 110 and a second circuit board surface 150B opposite to the first circuit board surface 150A. One or more driving circuit chips for applying power and signals to the film substrate 160 may be disposed on the PCB 150. The PCB 150 may transmit image data, a timing control signal, and the like to a display driver IC (DDI) 164 which will be described below. The PCB 150 may include a power circuit for supplying power to the DDI 164.

As shown in FIG. 3, the plurality of coupling areas CA may be formed in the display module 10. The plurality of coupling areas CA may each be disposed outside the perimeter of the PCB 150 in a state where a surface of the PCB 150 is viewed. In FIG. 3, it is shown that four coupling areas CA are disposed, but the number and arrangement of the coupling areas CA shown in the drawing are merely an example, and it should be noted that the number and arrangement of the coupling areas CA may be determined according to the design of the display module 10. As shown in FIG. 4A, one or more first connection pads 141 may be disposed in each coupling area CA to be exposed to the outside of the lower redistribution layer 140. One or more second connection pads 151 electrically connected to a circuit line formed on the PCB 150 may be disposed on the second circuit board surface 150B (e.g., a surface facing the −Z direction) of the PCB 150 opposite to the lower redistribution layer 140.

One or more second connection pads 151 electrically connected to the circuit line of the PCB 150 may be formed on the surface (e.g., the −Z direction) of the PCB 150 opposite to the lower redistribution layer 140. As shown in FIG. 3, a plurality of connectors 152 in which the second connection pad 151 is disposed may be disposed on the PCB 150, and as will be described below, the film substrate 160 may be coupled to the second connection pad 151 to be electrically connected to the circuit line of the PCB 150 by fastening the film substrate 160 to the connector 152.

The film substrate 160 may be disposed on a rear surface 110B of the display substrate 110, and a pixel array formed on the front surface of the display substrate 110 may be electrically connected to the PCB 150 disposed on the rear surface of the display substrate 110. The film substrate 160 may also be referred to as a chip-on-film (COF) semiconductor package. A DDI 164 for driving the display module 10 may be disposed on the film substrate 160, as illustrated in FIG. 4A.

The film substrate 160 may include a first surface 160A facing the rear surface 110B of the display substrate 110 and a second surface 160B opposite to the first surface 160A. The film substrate 160 may have a longitudinal direction (e.g., a longitudinal direction parallel to a Y axis of FIG. 4B), and may include a first coupling portion 1601 and a second coupling portion 1602 formed at both ends in the longitudinal direction, and a connection portion 1603 connecting the first coupling portion 1601 and the second coupling portion 1602. The film substrate 160 may be coupled to the first connection pad 141 disposed in the connection area CA through the first coupling portion 1601 to be electrically connected to the through via 120 corresponding to the coupled first connection pad 141. The film substrate 160 may be connected to the PCB 150 through the second coupling portion 1602 to be electrically connected to the circuit line of the PCB 150.

The film substrate 160 may include an insulating film 161, a wiring layer 162 that forms a wire on a surface of the insulating film 161, a protective layer 167, and a DDI 164 mounted on the surface of the film substrate 160. The film substrate 160 may include a mounting area M in which the DDI 164 is mounted. For example, the mounting area M may be formed in the connection portion 1603 of the film substrate 160. It should be noted that a position of the mounting area M on the film substrate 160 may be determined in various ways depending on the package design of the display module 10.

The insulating film 161 may be, for example, a flexible film. For example, the insulating film 161 may be a flexible film containing PI or an epoxy-based resin.

The wiring layer 162 may be disposed on at least a portion of the surface of the insulating film 161. The wiring layer 162 may be formed of a conductive material, for example, copper (Cu) plating, but the material of the wiring layer 162 is not limited thereto.

For example, the wiring layer 162 may include a first wiring layer 162 stacked on the surface of the insulating film to be formed on the first surface 160A of the film substrate 160. The first wiring layer 162 may form one or more first wires 162-1 and 162-2 extending along the longitudinal direction of the film substrate 160. The wire formed by the first wiring layer 162 may extend from the first coupling portion 1601 of the insulating film to the second coupling portion 1602 across the connection portion 1603. In some examples, the first wiring layer 162 may include a (1-1)-th wire 162-1 extending from the first coupling portion 1601 to the mounting area M and a (1-2)-th wire 162-2 extending from the mounting area M to the second coupling portion 1602. In an example, the (1-2)-th wire 162-2 may be an input wire for the DDI 164, and the (1-1)-th wire 162-1 may be an output wire for the DDI 164. In the drawing, it is shown that one first wire is formed on the film substrate 160 along the longitudinal direction, but this is because the drawing shows a cross section of the film substrate 160 for convenience of description, and it should be noted that a plurality of first wires that functions as a signal line or a power line may be formed on the film substrate 160.

One or more first coupling pads 1621 connected to each first wire 162-1 may be formed in the first coupling portion 1601. For example, the first coupling pad 1621 may be connected to an end (e.g., an end in the −Y direction) of the (1-1)-th wire 162-1, and exposed onto the first surface 160A of the first coupling portion 1601. The first coupling pad 1621 may be referred to as the exposed end of the (1-1)-th wire 162-1.

One or more second coupling pads 1622 connected to the respective first wires 162-1 and 162-2 may be formed in the second coupling portion 1602. For example, the second coupling pad 1622 may be connected to an end (e.g., an end in the +Y direction) of the (1-2)-th wire 162-2, and exposed onto the first surface 160A of the second coupling portion 1602. The second coupling pad 1622 may be referred to as the exposed end of the (1-2)-th wire 162-2.

As shown in FIG. 4A, the film substrate 160 may be bonded to one connection area CA on the rear surface 110B of the display substrate 110 through the first coupling portion 1601. The first coupling pad 1621 formed in the first coupling portion 1601 may be coupled to the first connection pad 141 formed in the connection area CA. A first conductive bonding film 171 may be disposed between the first coupling portion 1601 and the connection area CA, for example, between the first coupling pad 1621 and the first connection pad 141. The first conductive bonding film 171 may be, for example, an anisotropic conductive film (ACF). The first conductive bonding film 171 may be hardened during a process of pressing to bond the first coupling portion 1601 to the connection area CA and may electrically connect and bond the first coupling portion 1601 and the connection area CA.

The film substrate 160 may be connected to the PCB 150 through the second coupling portion 1602. For example, the second coupling portion 1602 of the film substrate 160 may be detachably fastened to the connector 152. In a state where the second coupling portion 1602 is fastened to the connector 152, the second coupling pad 1622 formed in the second coupling portion 1602 may be coupled to the second connection pad 151 disposed inside the connector 152.

The film substrate 160 may include a reinforcing member 168 disposed to cover the second surface 160B of the second coupling portion 1602. The reinforcing member 168 may be formed of an insulating material, and may increase a thickness of the second coupling portion 1602 to improve a rigidity of the second coupling portion 1602 to be coupled to the PCB 150. Since the film substrate 160 has a thin thickness and is flexible, when the reinforcing member 168 is disposed in the second coupling portion 1602, a process of fastening the second coupling portion 1602 to the connector 152 may be more easily performed, and the increase of the thickness of the second coupling portion 1602 due to the reinforcing member 168 may reduce or prevent a phenomenon that the second coupling portion 1602 fastened to the connector 152 is detached from the connector 152. The second coupling portion 1602 is electrically coupled to the second connection pad 151 of the PCB 150 through the second coupling pad 1622 formed on the first surface 160A. Therefore, although the reinforcing member 168 is disposed on the second surface 160B of the second coupling portion 1602, it may not interfere with the electrical connection of the second coupling pad 1622 and the second connection pad 151.

The protective layer 167 may be disposed on the surface of the film substrate 160 to cover the wires of the film substrate 160. The protective layer 167 may be formed of a resist film. The protective layer 167 may be bonded to the surface of the film substrate 160, for example, by applying a solder resist to the surface of the film substrate 160 by screen printing or spray coating or by laminating a film-type solder resist material. However, the protective layer 167 is not limited thereto, and it should be noted that the protective layer 167 may be formed with various materials and by various methods that may protect the wires 162-1 and 162-2 formed on the film substrate 160.

The protective layer 167 (or a portion of the protective layer 167) may be omitted to expose a portion of the wire on at least a portion of the surface of the film substrate 160. For example, a portion of the protective layer 167 may be omitted to expose the end of the (1-1)-th wire 162-1 or the first coupling pad 1621 in the first coupling portion 1601. Similarly, a portion of the protective layer 167 may be omitted to expose the end of the (1-2)-th wire 162-2 or the second coupling pad 1622 in the second coupling portion 1602.

The protective layer 167 (or a portion of the protective layer 167) may be omitted to expose a portion of the first wire in the mounting area M of the film substrate 160. For example, a portion of the protective layer 167 may be omitted from the mounting area M so as to expose an end portion of the (1-1)-th wire 162-1 and an end portion of the (1-2)-th wire 162-2 extending to the mounting area M. As the protective layer 167 is omitted from the mounting area M, the DDI 164 may be connected to the first wire.

The DDI 164 may drive a pixel array of the display module 10. The DDI 164 may generate a gate signal based on a control signal transmitted from the PCB 150 and generate a data signal based on image data transmitted from the PCB 150. A signal output from the DDI 164 may be input to a driving circuit of the driving circuit layer 131.

The DDI 164 may be electrically connected to the first wires 162-1 and 162-2. For example, as shown in FIG. 4B, a semiconductor chip may be mounted on the first surface 160A of the film substrate 160 in the mounting area M of the film substrate 160. The DDI 164 may include a first chip pad 1641 and a second chip pad 1642. The first chip pad 1641 of the DDI 164 may be connected to the end portion of the (1-1)-th wire 162-1 exposed in the mounting area M. The first chip pad 1641 may be an output terminal of the DDI 164. The second chip pad 1642 of the DDI 164 may be connected to the end portion of the (1-2)-th wire 162-2 exposed in the mounting area M. The second chip pad 1642 may be an input terminal of the DDI 164. The DDI 164 may be bonded to the surface of the film substrate 160 in the mounting area M by a flip chip bonding method, but the method of mounting the DDI 164 onto the film substrate 160 is not limited thereto.

In the display module 10, the film substrate 160 may be electrically connected to the driving circuit layer 131 disposed on a front surface of glass through the first connection pad 141 and the through via 120 on the rear surface of the display substrate 110, and may be electrically connected to the PCB 150 on the rear surface 110B of the display substrate 110. According to such a structure, there is no need for separate side wires to connect the pixel array disposed on the driving circuit layer 131 and the PCB 150, and thus, a separate dummy area or inactive area for wire formation may be omitted in a display area formed on the front surface of the display substrate 110. Therefore, the entire front surface of the display substrate 110 may be utilized as an active area. Therefore, the display module 10 with a bezel-less structure may be manufactured.

In addition, since the film substrate 160 is disposed only on the rear surface 110B of the display substrate 110, a degree of freedom in the position of the mounting area M disposed on the DDI 164 on the film substrate 160 may be improved. For example, when the DDI 164 is disposed adjacent to the PCB 150, a more advantageous heat dissipation design may be possible when forming a housing outside the display module 10.

Since the display module 10 may couple the film substrate 160 to the PCB 150 without separate components such as a flexible PCB (FPCB), a separate process for bonding the film substrate 160 and the FPCB may be omitted, thereby reducing the process time and cost required to manufacture the display module 10.

FIG. 4C is an enlarged cross-sectional view of an exemplary film substrate.

Referring to FIG. 4C, a film substrate 160c may include the insulating film 161, the wiring layer 162 that forms a wire on the first surface 160A of the film substrate 160C, the DDI 164 to be mounted onto the film substrate 160C, and the protective layer 167 that covers at least a portion of the surface of the film substrate 161. The wiring layer 162 may include one or more first wires 162-1 extending from the first coupling portion 1601 to the connection portion 1603 of the film substrate 160C, and one or more second wires 162-2 extending from the second coupling portion 1602 to the connection portion 1603 of the film substrate 160C. The first wire 162-1 and the second wire 162-2 may be electrically connected to the DDI 164. The protective layer 167 may be disposed on the first surface 160A and the second surface 160B of the film substrate 160C. The protective layer 167 may cover at least a portion of the wiring layer 162 on the first surface 160A of the film substrate 160C.

Protective layers 167-1 and 167-2 may be disposed on the second surface 160B of the film substrate 160C. The protective layers 167-1 and 167-2 disposed on the second surface 160B of the film substrate 160C may increase the thickness of the film substrate 160C to improve the rigidity. The protective layers 167-1 and 167-2 may have different thicknesses depending on the position of the film substrate 160C. For example, in the second coupling portion 1602 of the film substrate 160C, the protective layer 167-2 disposed on the second surface 160B may be formed to have a thickness greater than that of the protective layer 167-1 disposed in the first coupling portion 1601 and/or the connection portion 1603. For example, the second coupling portion 1602 of the film substrate 160C may have a thickness and a rigidity greater than those of the connection portion 1603, by the protective layer 167-2 disposed on the second surface 160B of the second coupling portion 1602.

In another example, the protective layer 167-1 may be omitted from the second surface 160B of the first coupling portion 1601 and the connection portion 1603 of the film substrate 160C, and the protective layer 167-2 may be formed only on the second surface 160B of the second coupling portion 1602.

When the second coupling portion 1602 of the film substrate 160C has a thickness greater than the other portions 1601 and 1603, the process in which the film substrate 160C fastens the second coupling portion 1602 to a connector (e.g., the connector 152 of FIG. 4A) of a PCB may be performed more easily.

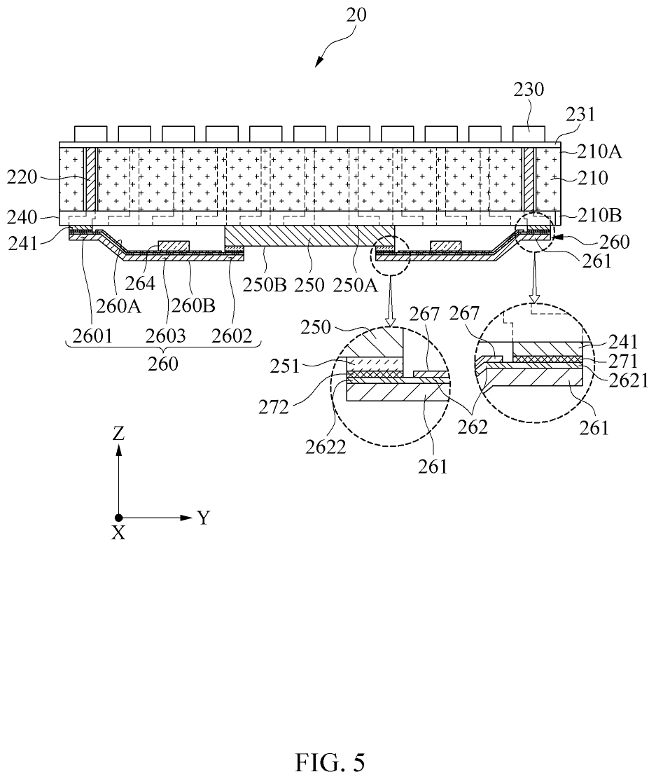

FIG. 5 is an exemplary cross-sectional view of a display module taken along line A-A′ of FIG. 3.

Referring to FIG. 5, a display module 20 according to an embodiment may include a display substrate 210 on which a plurality of through vias 220 are formed, a plurality of micro LEDs 230 that forms a plurality of pixel arrays on a front surface 210A of the display substrate 210, a PCB 250 disposed on a rear surface 210B of the display substrate 210, and a film substrate 260 coupled to each of the PCB 250 and a through via 220 on the rear surface 210B of the display substrate 210. The display substrate 210 may be, for example, a glass substrate.

The PCB 250 may be disposed so that a first circuit board surface 250A faces the display substrate 210. A second connection pad 251 electrically connected to a circuit line of the PCB 250 may be disposed to be exposed on a second circuit board surface 250B of the PCB. The film substrate 260 may be bonded to a first connection pad 241 exposed to the outside of a lower redistribution layer 240 through a first coupling pad 2621 formed in a first coupling portion 2601 and connected to an end portion of a first wire 262, and may be bonded to a second connection pad 251 of the PCB 250 through a second coupling pad 2622 formed in a second coupling portion 2602 and connected to an end portion of the first wire 262. A first conductive bonding member 271 may be disposed between the first connection pad 241 and the first coupling pad 2621. A second conductive bonding member 272 may be disposed between the second connection pad 251 and the second coupling pad 2622. The conductive bonding members 271 and 272 may bond the connection pads 241 and 251 and the coupling pads 2621 and 2622, respectively, and at the same time, may form electrical paths between the connection pads 241 and 251 and the coupling pads 2621 and 2622, respectively.

The film substrate 260 may input a signal transmitted from the PCB 250 to a driver driving chip 264 mounted on a connection portion 2603, and transmit the signal output from the driver driving chip 264 to a driving circuit of a driving circuit layer 231 through the first connection pad 241 and the through via 220. The micro LED 230 forming each pixel of the display module 20 may be driven through the signal transmitted to the driving circuit layer 231.

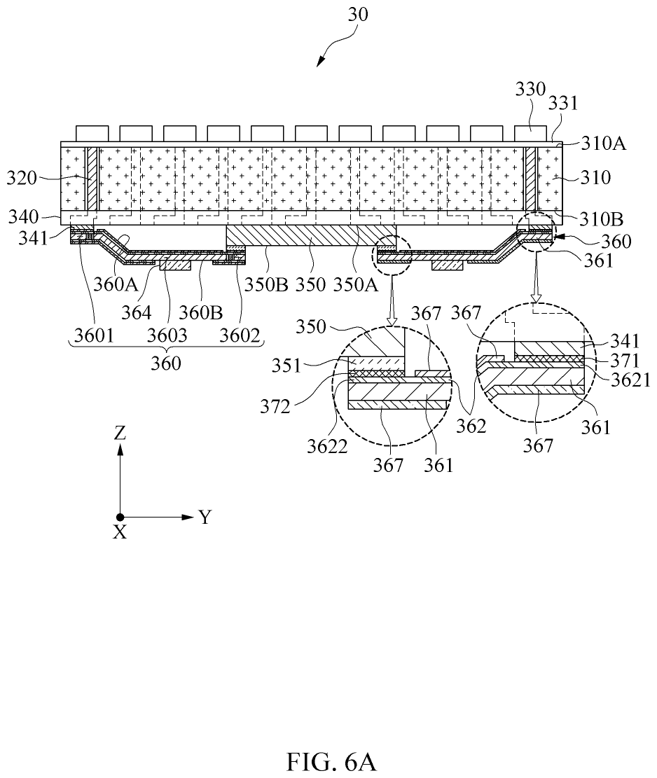

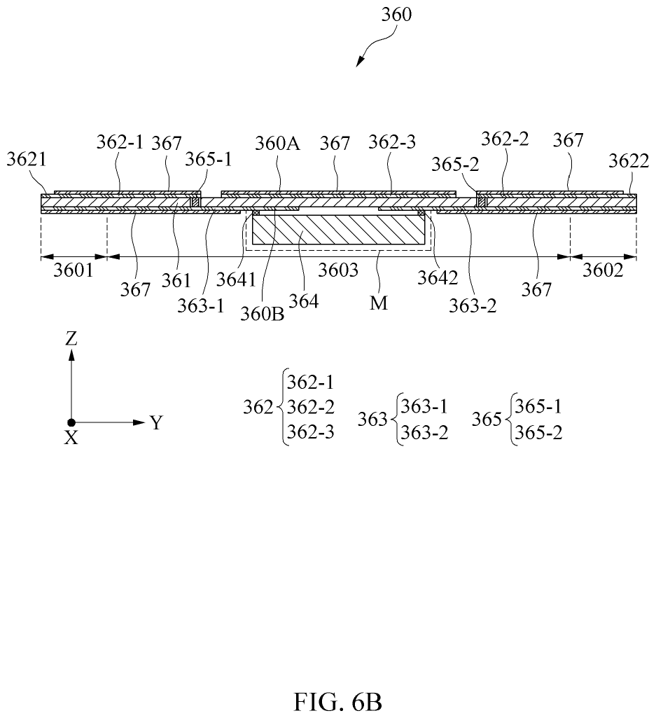

FIG. 6A is an exemplary cross-sectional view of a display module taken along line A-A′ of FIG. 3. FIG. 6B is an enlarged cross-sectional view of a film substrate shown in FIG. 6A.

Referring to FIGS. 6A and 6B, a display module 30 according to an embodiment may include a display substrate 310 on which a plurality of through vias 320 are formed, a plurality of micro LEDs 330 disposed on a protective circuit layer 331 formed on a front surface of the display substrate 310 to form a plurality of pixel arrays, a PCB 350 disposed on a rear surface of the display substrate 310, and a film substrate 360 coupled to each of the PCB 350 and the through via 320 on the rear surface of the display substrate 310.

A second connection pad 351 electrically connected to a circuit line of the PCB 350 may be disposed to be exposed on the surface (e.g., a surface facing the −Z direction) of the PCB 350.

The film substrate 360 may include a first wiring layer 362 stacked on a surface of an insulating film 361 to be formed on a first surface 360A, and a second wiring layer 363 stacked on the surface of the insulating film 361 to be formed on a second surface 360B.

The first wiring layer 362 may form one or more first wires 362-1 and 362-2 extending along a longitudinal direction of the film substrate 360. The first wiring layer 362 may include one or more (1-1)-th wires 362-1 extending from a first coupling portion 3601 to a connection portion 3603, and one or more (2-2)-th wires 363-2 extending from the connection portion 3603 to a second coupling portion 3602. A first coupling pad 3621 may be connected to an end of the (1-1)-th wire 362-1 in the first coupling portion 3601. The first coupling pad 3621 may be exposed on the first surface 360A of the film substrate 360. A second coupling pad 3622 may be connected to an end of the (1-2)-th wire 362-2 in the second coupling portion 3602. The second coupling pad 3622 may be exposed on the second surface 360B of the film substrate 360. The first wiring layer 362 may include a (1-3)-th wire 362-3 disposed in the connection portion 3603.

The second wiring layer 363 may form one or more second wires 363-1 and 363-2 on the second surface 360B along the longitudinal direction of the film substrate 360. The second wiring layer 363 may include a (2-1)-th wire 363-1 connected from a mounting area M formed in the connection portion 3603 to at least a portion of the first coupling portion 3601, and a (2-2)-th wire 363-2 connected from the mounting area M to at least a portion of the second coupling portion 3602.

When viewed in a thickness direction (e.g., the Z-axis direction) of the film substrate 360, at least a portion of the (1-1)-th wire 362-1 and at least a portion of the (2-1)-th wire 363-1 may overlap each other, and at least a portion of the (1-2)-th wire 362-2 and at least a portion of the (2-2)-th wire 363-2 may overlap each other.

The film substrate 360 may include one or more connection vias 365 formed to penetrate the first surface 360A and the second surface 360B along the thickness direction, and electrically connecting the first wiring layer 362 and the second wiring layer 363. For example, the connection vias 365 may be formed in the connection portion 3603. The connection vias 365 may include one or more first connection vias 365-1 that electrically connect the (1-1)-th wire 362-1 and the second wires 363-1 and 363-2, and one or more second connection vias 365-2 that electrically connect the (1-2)-th wire 362-2 and the second wires 363-1 and 363-2. For example, the first connection via 365-1 may be formed in an area where the (1-1)-th wire 362-1 and the (1-2)-th wire 362-2 overlap. The second connection via 365-2 may be formed in a portion where the (1-2)-th wire 362-2 and the (2-2)-th wire 363-2 overlap.

A protective layer 367 may be formed on the surface of the film substrate 360 to cover each of the first wiring layer 362 and the second wiring layer 363. The protective layer 367 may be stacked on each of the first surface 360A and the second surface 360B. The protective layer 367 may be omitted to expose the wire on at least a portion of the surface of the film substrate 360. For example, the protective layer 367 may be omitted to expose the end of the (1-1)-th wire 362-1 or the first coupling pad 3621 in the first coupling portion 3601, and may be omitted to expose the end of the (1-2)-th wire 362-2 or the second coupling pad 3622 in the second coupling portion 3602.

The protective layer 367 may be omitted to expose a portion of the second wire in the mounting area M of the film substrate 360. For example, the protective layer 367 may be omitted from the mounting area M to expose an end portion of the (2-1)-th wire 363-1 and an end portion of the (2-2)-th wire 363-2 positioned in the mounting area M. A driver driving chip 364 may be connected to a portion of the second wire exposed in the mounting area M.

The driver driving chip 364 may be mounted on the second surface 360B of the film substrate 360. The driver driving chip 364 may be connected to an exposed end portion of the (2-1)-th wire 363-1 through a first chip pad 3641, and may be connected to an exposed end portion of the (2-2)-th wire 363-2 through a second chip pad 3642. The first chip pad 3641 may be an output terminal of the driver driving chip 364, and the second chip pad 3642 may be an input terminal of the driver driving chip 364.

The film substrate 360 may be formed of a multi-layer including the insulating film 361, and the first wiring layer 362 and the second wiring layer 363 stacked on both surfaces of the insulating film 361. When the second wiring layer 363 extends to an end portion of the second coupling portion 3602, a thickness of the second coupling portion 3602 may relatively increase, compared to a case where only the first wiring layer 362 is formed on the film substrate 360. In this case, when the second coupling portion 3602 is coupled to the PCB 350 through a connector, the fastening process of the second coupling portion 3602 to the connector may be performed more easily.

The film substrate 360 may be bonded to a first connection pad 341 formed in the first coupling portion 3601 and exposed to the outside of a lower redistribution layer 340 through the first coupling pad 3621 connected to an end portion of the (1-1)-th wire 362-1, and bonded to the second connection pad 351 formed in the second coupling portion 3602 and formed on the PCB 350 through the second coupling pad 3622 connected to an end portion of the (1-2)-th wire 362-2. A first conductive bonding member 371 may be disposed between the first connection pad 341 and the first coupling pad 3621. A second conductive bonding member 372 may be disposed between the second connection pad 351 and the second coupling pad 3622. Although not shown, on the surface of the PCB 350, as shown in FIG. 4B, a connector, in which the second connection pad 351 is disposed, may be disposed, and the second connection pad 351 and the second coupling pad 3622 may be coupled through the fastening of the film substrate 360 to the connector.

A signal input from the PCB 350 to the second coupling pad 3622 may be transmitted to the (2-2)-th wire 363-2 through the (1-2)-th wire 362-2 and the second connection via 365-2 to be input to the driver driving chip 364. The signal output from the driver driving chip 364 may be transmitted to the (1-1)-th wire 362-1 through the (2-1)-th wire 363-1 and the first connection via 365-1 to be output through the first coupling pad 3621.

Through the first wiring layer 362 and the second wiring layer 363 formed on the first surface 360A and the second surface 360B of the film substrate 360, a degree of freedom of a circuit design in the film substrate 360 may increase. Also, since the driver driving chip 364 may be mounted on the second surface 360B, the degree of freedom in designing the arrangement of the driver driving chip 364 on the film substrate 360 may be improved.

As described above, although the embodiments have been described with reference to the limited drawings, a person skilled in the art may apply various technical modifications and variations based thereon. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and equivalents of the claims are within the scope of the following claims.

What is claimed is:

1. A display module comprising:
a display substrate comprising a front surface and a rear surface opposite to the front surface;
an array of pixels on the front surface of the display substrate, wherein a plurality of micro light emitting diodes (LEDs) are in each pixel in the array of pixels;
a plurality of through vias in the display substrate that extend from the front surface of the display substrate to the rear surface of the display substrate;
a printed circuit board (PCB) on the rear surface of the display substrate; and
a film substrate on the rear surface of the display substrate and comprising a first coupling portion coupled to at least one of the plurality of through vias, a second coupling portion coupled to the PCB, and a connection portion that connects the first coupling portion and the second coupling portion,
wherein each of the plurality of through vias is electrically connected to at least one pixel in the array of pixels, and
wherein the film substrate comprises:
an insulating film;
a wiring layer on at least a portion of a surface of the insulating film, wherein the wiring layer comprises at least one wire extending from the first coupling portion and the second coupling portion; and
a display driver IC (DDI) on a surface of the film substrate and electrically connected to the at least one wire.

2. The display module of claim 1, wherein
the film substrate further comprises a first surface facing the rear surface of the display substrate and a second surface opposite to the first surface, and
at least one first coupling pad connected to the at least one wire on the first surface of the film substrate at the first coupling portion, and at least one second coupling pad connected to the at least one wire on the second surface of the film substrate at the second coupling portion.

3. The display module of claim 2, further comprising at least one coupling area on the rear surface of the display substrate, wherein the at least one coupling area comprises at least one first connection pad, and wherein the at least one first connection pad is electrically connected to a respective one of the plurality of through vias, and
wherein the first coupling portion of the film substrate is bonded to the at least one coupling area so that the at least one first coupling pad is coupled to the at least one first connection pad.

4. The display module of claim 3, wherein
the at least one coupling area is spaced apart from an outer perimeter of the PCB.

5. The display module of claim 3, further comprising:
a lower redistribution layer on the rear surface of the display substrate, wherein the lower distribution layer comprises a redistribution line that connects the respective one of the plurality of through vias and the at least one first connection pad.

6. The display module of claim 3, further comprising:
a first conductive bonding film between the at least one first connection pad and the at least one first coupling pad.

7. The display module of claim 2, wherein
at least one second connection pad electrically connected to a circuit line of the PCB is on a surface of the PCB, and
wherein the second coupling portion of the film substrate is bonded to a surface of the PCB so that the at least one second coupling pad is coupled to the at least one second connection pad.

8. The display module of claim 7, further comprising:
a second conductive bonding film between the at least one second connection pad and the at least one second coupling pad.

9. The display module of claim 2, wherein
the PCB comprises at least one connector electrically connected to a circuit line of the PCB, and
wherein the second coupling portion of the film substrate is detachably fastened to the at least one connector.

10. The display module of claim 6, wherein the film substrate further comprises a reinforcing member on the second surface of the film substrate at the second coupling portion, and wherein the reinforcing member is configured to provide rigidity to the second coupling portion.

11. The display module of claim 2, wherein
the film substrate further comprises a first wiring layer comprising at least one first wire on the first surface of the film substrate, and
wherein the DDI is on the first surface of the film substrate and electrically connected to the at least one first wire.

12. The display module of claim 2, wherein
the film substrate further comprises:
a first wiring layer comprising at least one first wire on the first surface of the film substrate;
a second wiring layer comprising at least one second wire on the second surface of the film substrate; and
at least one connection via that penetrates the first surface and the second surface of the film substrate and electrically connects the first wiring layer and the second wiring layer, and
wherein the DDI is on the second surface of the film substrate and electrically connected to the at least one second wire in the connection portion.

13. The display module of claim 12, wherein
the first wiring layer comprises at least one (1-1)-th wire extending from the first coupling portion to the connection portion, and at least one (1-2)-th wire extending from the second coupling portion to the connection portion, and
the at least one connection via comprises:
at least one first connection via in the connection portion and electrically connecting the (1-1)-th wire and the second wire; and
at least second connection via in the connection portion and electrically connecting the (1-2)-th wire and the second wire.

14. The display module of claim 1, wherein
the second coupling portion of the film substrate has a thickness greater than a thickness of the connection portion.

15. The display module of claim 12, further comprising:
a protective insulating layer that covers the at least one first wire,
wherein the at least one first wire is exposed on at least a portion of a mounting area for a semiconductor chip.

16. A display device comprising:
a plurality of display modules arranged in an array,
wherein each of the display modules comprises:
an array of pixels on a front surface of a display substrate, wherein a plurality of micro LEDs are in each pixel;
a plurality of through vias that penetrate the display substrate and extend from the front surface of the display substrate to a rear surface of the display substrate;
a PCB on the rear surface of the display substrate; and
a film substrate on the rear surface of the display substrate and comprising a first coupling portion coupled to at least one of the plurality of through vias, a second coupling portion coupled to the PCB, and a connection portion that connects the first coupling portion and the second coupling portion,
wherein each of the plurality of through vias is electrically connected to at least one pixel in the array of pixels, and
wherein the film substrate comprises:
an insulating film;
a wiring layer on at least a portion of a surface of the insulating film, wherein the wiring layer comprises at least one wire extending from the first coupling portion and the second coupling portion; and
a DDI on a surface of the film substrate and electrically connected to the at least one wire.

17. The display device of claim 16, wherein
the film substrate further comprises a first surface facing the rear surface of the display substrate and a second surface opposite to the first surface, and
wherein at least one first coupling pad is connected to each at least one wire on a first surface of the first coupling portion, and at least one second coupling pad is connected to each at least one wire on a second surface of the second coupling portion.

18. The display device of claim 17, wherein
each of the display modules further comprises:
a plurality of first connection pads on the rear surface of the display substrate; and
a lower redistribution layer on the rear surface of the display substrate, and comprising a redistribution line for connecting the plurality of through vias and the plurality of first connection pads,
wherein at least one coupling area is on the rear surface of the display substrate and the first coupling portion of the film substrate is bonded to the at least one coupling area so that the at least one first coupling pad is coupled to a respective one of the plurality of first connection pads.

19. The display device of claim 17, wherein
each of the plurality of display modules comprises at least one second connection pad on a surface of the PCB that is electrically connected to a circuit line of the PCB, and wherein the film substrate is connected to the PCB so that the at least one second coupling pad is coupled to the at least one second connection pad, and
wherein the first coupling portion is bonded to the PCB or detachably fastened to a connector on the PCB.

20. A display module comprising:
a display substrate comprising a front surface and a rear surface opposite to the front surface;
an array of pixels on the front surface of the display substrate, wherein a plurality of micro LEDs are in each pixel in the array of pixels;
a plurality of through vias in the display substrate that extend from the front surface of the display substrate to the rear surface of the display substrate;
a PCB on the rear surface of the display substrate; and
a film substrate on the rear surface of the display substrate and comprising a first coupling portion coupled to at least one of the plurality of through vias, a second coupling portion coupled to the PCB, and a connection portion that connects the first coupling portion and the second coupling portion,
wherein each of the plurality of through vias is electrically connected to at least one pixel in the array of pixels, and
wherein the film substrate further comprises:
an insulating film;
a wiring layer on at least a portion of a surface of the insulating film, wherein the wiring layer comprises at least one wire extending from the first coupling portion and the second coupling portion; and
a DDI on a surface of the film substrate and electrically connected to the at least one wire,
wherein the film substrate further comprises a first surface facing the display substrate and a second surface opposite to the first surface, and wherein the at least one wire is exposed through the film substrate first surface at the first coupling portion and at the second coupling portion,
wherein the first coupling portion is bonded onto the rear surface of the display substrate so that the exposed at least one wire is electrically connected to at least one of the plurality of through vias, and
wherein the second coupling portion is connected to the PCB so that the exposed at least one wire is electrically connected to a circuit line of the PCB.
